(19) United States
(12) Patent Application Publication
(10) Pub. No.: US 2006/0214535 A1
(43) Pub. Date: Sep. 28, 2006

(54) Energy converter utilizing electrostatics

(76) Inventor: Peter C. Salmon, Mountain View, CA (US)

Correspondence Address: Edward N. Bachand;DORSEY & WHITNEY LLP, Suite 1000, 555 California Street, San Francisco, CA, 94104-1513, US

(21) Appl. No.: 11/387,514

(22) Filed: Mar. 22, 2006

Related U.S. Application Data
(60) Provisional application No. 60/664,321, filed on Mar. 22, 2005.

(51) Int. Cl. H02N 1/00; H01L 41/04

(52) U.S. Cl. 310/309; 318/116; 322/2 A

(57) ABSTRACT

An electrostatic energy converter comprising a rotor having a working surface provided with a plurality of distinct charged regions. A stator extends parallel to the rotor and has a working surface facing the working surface of the rotor and being provided with a plurality of spaced-apart electrodes. A power supply is coupled to the electrodes.

### CROSS REFERENCE TO RELATED APPLICATIONS

This application claims priority to Provisional Application Ser. No. 60/664,321 filed Mar. 22, 2005, the entire content of which is incorporated herein by reference this reference.

### FIELD OF THE INVENTION

This invention relates to energy converters and more particularly to electrostatic motors and generators.

### DESCRIPTION OF THE RELATED ART

Energy converters such as electric motors employing electromagnetic forces have been the dominant motor type for many decades. Generally they comprise a moving element and a stationary element, at least one of which includes coils through which current is passing to create a magnetic field. This magnetic field acts on a permanent magnet or on a coil carrying current provided on the other member to create a motive force by which relative motion between the elements is produced. The coils are formed in three dimensions and this limits the compactness of electromagnetic motors and generators. Additionally, the motive force is proportional to the current in the coils, and this current causes resistive losses that limit the energy efficiency.

Electrostatic motors have also been described. Many of them require electrical connections to the moving rotor element. Typically these take the form of brushes or spring elements that contact rotor electrodes. These electrical connections can reduce reliability and increase manufacturing cost, as well as require periodic maintenance.

Many electrostatic motors previously described are intended for micro motor applications such as may be useful in watches or micro-electrical-mechanical devices (MEMS). Typically these motors use micro-machining fabrication methods involving removal of sacrificial layers to separate the moving element from the stationary elements.

Other electrostatic motors employ working elements that are supported on curved surfaces, typically cylindrical in shape. Since most manufacturing processes are adapted to flat substrates rather than curved substrates, planar working surfaces are usually preferred with respect to motor fabrication costs.

### SUMMARY OF THE INVENTION

An electrostatic energy converter is provided and includes a rotor having a working surface provided with a plurality of distinct charged regions. A stator extends parallel to the rotor and has a working surface facing the working surface of the rotor and being provided with a plurality of spaced-apart electrodes. A power supply is coupled to the electrodes.

### BRIEF DESCRIPTION OF THE DRAWINGS

The accompanying drawings, which are somewhat schematic in some instances and are incorporated in and form a part of this specification, illustrate several embodiments of the invention and, together with the description, serve to explain the principles of the invention.

FIG. 1 is a cross-sectional view of a vehicle provided with first and second energy converters of the present invention.

FIG. 2 is a cross-sectional view of an energy converter utilizing electrostatics of the present invention.

FIG. 3 is a top plan view of a rotor disk in the energy converter of FIG. 2 taken along the line 3-3 of FIG. 2.

FIG. 4 is a cross-sectional view of the rotor disk of FIG. 3 taken along the line 4-4 of FIG. 3.

FIG. 5 is a top plan view of a stator disk in the energy converter of FIG. 2 taken along the line 5-5 of FIG. 2.

FIG. 6 is a cross-sectional view of the stator disk of FIG. 5 taken along the line 6-6 of FIG. 5.

FIG. 7 is an expanded cross-sectional view of a portion of energy converter of FIG. 2 taken along the circle 7-7 of FIG. 2.

FIG. 8 is a top plan view of the rotor disk of FIG. 3 overlaying the stator disk of FIG. 5.

FIG. 9 is a schematic block diagram of a controller for use in the energy converter of FIG. 2.

FIG. 10 is a graph of a three-phase voltage traveling wave.

FIG. 11 is a graph of motor load angle α.

FIG. 12 is a graph of load torque versus load angle.

FIG. 13 is a graph of maximum available torque versus angular velocity.

FIG. 14 is a schematic view of the working surfaces of an adjacent rotor disk and stator disk.

FIG. 15 is a one-dimensional model for calculating force, torque, and power developed in an energy converter of the present invention.

FIG. 16 is a graph of the calculated variation in torque for an energy converter of the present invention.

FIG. 17 is a graph of the velocity versus time for the vehicle of FIG. 1.

FIG. 18 is a waveforms for the phase voltage Φ1 corresponding to the graph of velocity of FIG. 17.

FIG. 19 is a graph of voltage versus time resulting from applying power in a pulsed manner with the controller of FIG. 9 to a stator phase voltage.

FIG. 20 is a cross-sectional view of another embodiment of an energy converter of the present invention.

FIG. 21 is a cross-sectional view of a further embodiment of an energy converter of the present invention.

FIG. 22 is a first phase power option for the energy converter of FIG. 21.

FIG. 23 is a second phase power option for the energy converter of FIG. 21.

FIG. 24 is a third phase power option for the energy converter of FIG. 21.

FIG. 25 is a perspective view of a compact motorized tool of the present invention.

FIG. 26 is a side view of the motorized tool of FIG. 25 taken along the line 26-26 of FIG. 25.

### DETAILED DESCRIPTION OF THE PREFERRED EMBODIMENTS

Various embodiments of the present invention are described hereinafter with reference to the figures. It should also be noted that the figures are only intended to facilitate the description of specific embodiments of the invention. They are not intended as an exhaustive description of the invention or as a limitation on the scope of the invention. In addition, an aspect described in conjunction with a particular embodiment of the present invention is not necessarily limited to that embodiment and can be practiced in any other embodiments.

For instance, energy converters are described including both an energy conversion portion and a controller portion. It will be appreciated that these can be packaged and used separately. Although the preferred embodiments include application for transportation vehicles, industrial motor/generators, and hand-held compact motors, other embodiments and applications will be apparent to those who are skilled in the art.

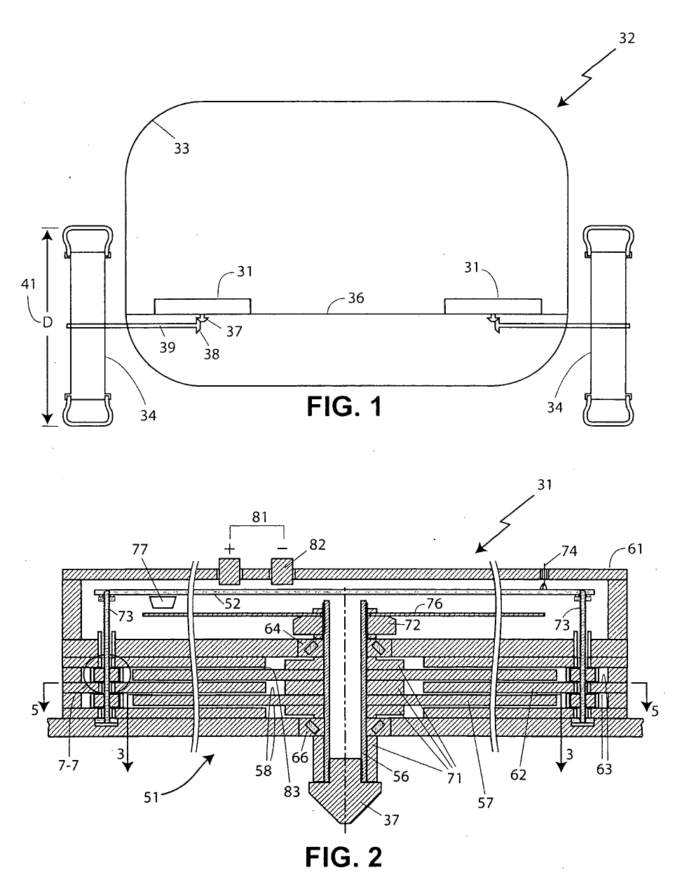

An energy converter utilizing electrostatics of the present invention can be in many forms, such as an electrostatic motor or an electrostatic generator. A device utilizing an energy converter 31 of the present invention is illustrated in FIG. 1, where a vehicle 32 having a frame 33 is shown. At least first and second energy converters 31 are utilized in the vehicle. One energy converter 31 is preferably located next to each powered wheel 34. It is also possible to drive multiple wheels with a single motor 31, depending on the drive linkages. Each converter 31 is mounted on a cross or support member 36 of the frame 33 and a drive gear 37 extends through the cross member to drive the respective wheel 34 by means of mating gear 38 and mechanical linkage 39. Thus, the transmission and drive train are simple and small, and they can be applied to each wheel individually. Each wheel has a diameter 41.

A cross-sectional view of one of the energy converters 31 of FIG. 1 is illustrated in FIG. 2. Energy converter 31 includes an energy conversion portion or motor/generator 51 and a controller board or controller 52. Drive gear 37 is attached to a drive shaft 56. A plurality of rotors 57 are rigidly coupled to drive shaft 56, and have opposite first and second surfaces or faces 58. A housing 61 is provided and a plurality of stators 62 are rigidly coupled to the housing and disposed parallel to and in face-to-face relation with the rotors 57. In this regard, a rotor 57 is spaced between each adjacent pair of stators 62. Each of the stators has opposite first and second surfaces or faces 63. First and second thrust roller bearings 64 and 66 respectively engage the first or top and second or bottom of drive shaft 56 and thus the stack or rotors carried thereby. Spacers 71 are provided along the drive shaft 56, for example between adjacent rotors 57, and a locking nut 72 is utilized to tighten and bind the stack of rotors and spacers and the inner races of bearings 64 and 66 together against the drive gear 37 mounted on the bottom end of the shaft 56. As nut 72 is tightened, spacers 71 assert the correct spacing and also the proper alignment between rotors 57 and stators 62.

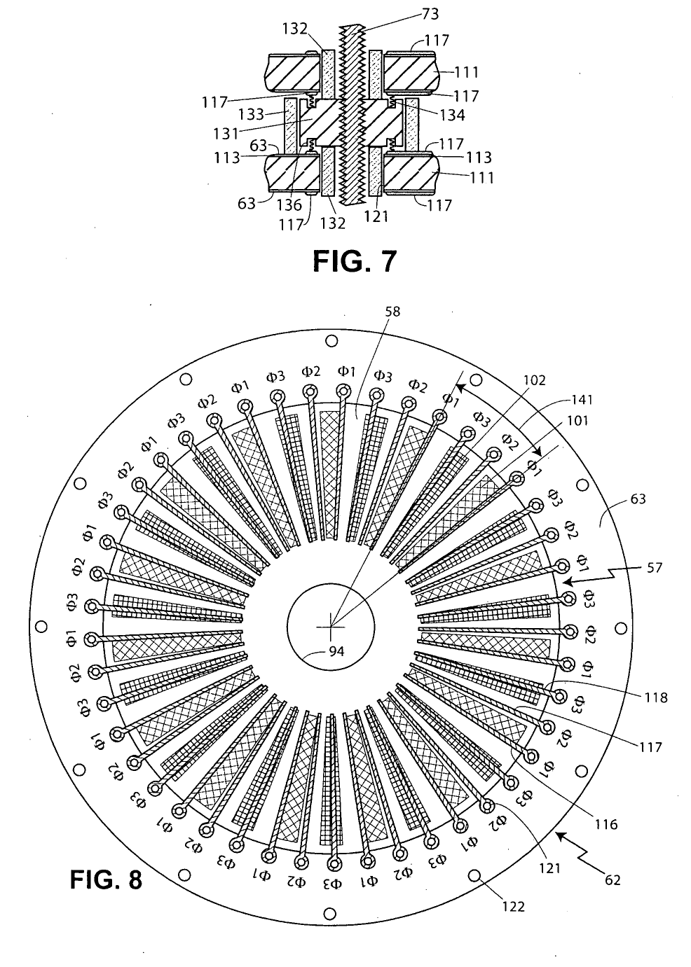

Power rods 73, each made from any suitable conductive material such as brass, connect phase drives (Φ_{1,2,3}) from controller board 52 to each of the stators 62; and further details of such connection is illustrated in FIG. 7. Control inputs 74, for example by the driver of vehicle 32, also connect with the controller board 52 and the signals to these inputs are provided by any suitable means such as a central control computer (not shown) and a rotary encoder employing encoder disk 76 mounted on drive shaft 56 for rotation within housing 61 and a sensor 77 rigidly coupled to the housing, for example to controller board 52. Positive and negative battery terminals 81 connect to isolated feedthroughs 82 in housing 61 and are shown providing input power to controller board 52. The feedthroughs 82 can also receive power in regenerative braking mode or generator mode of energy converter 31 as described below. A gap 83 is shown between each adjacent pair of rotors 57 and stators 62. The gap 83 is preferably approximately one millimeter, and is preferably air but can also be a vacuum or a liquid such as transformer oil. Other gases may be used in the gap 83, for example sulfur hexafluoride (SF₆) may be employed to reduce arcing.

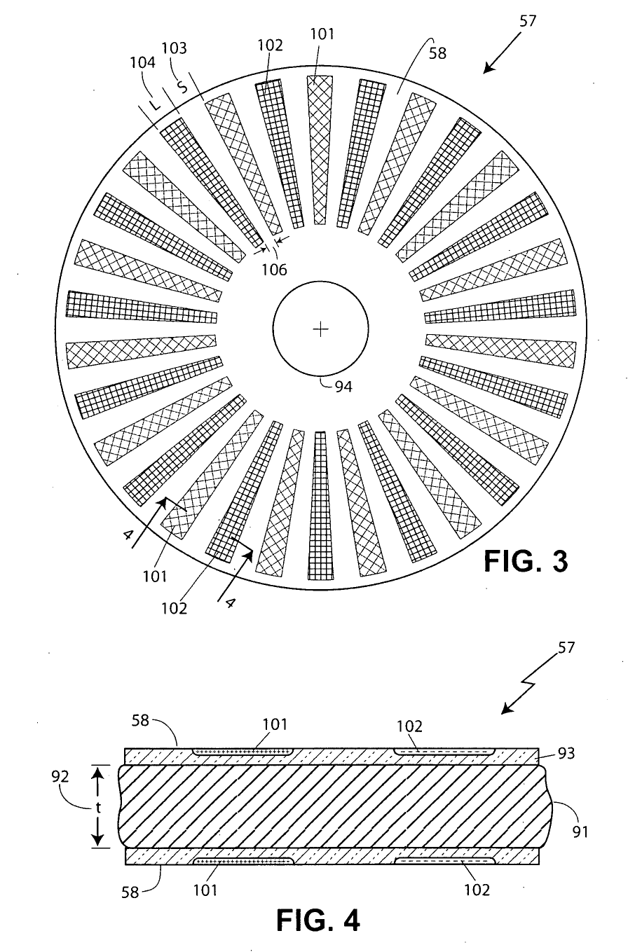

The construction of a rotor 57 of the present invention is shown in FIGS. 3 and 4. The rotor is formed from a substrate 91 that is preferably a planar disk formed from any suitable material such as a low expansion metal alloy such as Kovar. Substrate or disk 91 has a diameter that can range from 10 to 50 centimeters and is preferably approximately 25 centimeters, and has a thickness 92 ranging from one to ten millimeters and preferably approximately five millimeters. As such, the disk is substantially rigid. For smaller energy converters, less mechanical precision is required and substrate 91 may be made of an insulating material such as a plastic, ceramic or glass.

Disk 91 is preferably coated with any suitable insulating material such as glass to form a layer or coating 93 on each planar surface of the disk. The sealing glass or coating 93 provides a smooth and durable surface for embedding ion implanted charges. By matching the coefficients of thermal expansion (CTEs) of the metal alloy of substrate 91 and the glass, coating 93 is not highly stressed and does not have a tendency to crack. Selected borosilicate glasses have similar expansion characteristics to Kovar and also have good mechanical properties. Because borosilicate glass is a rigid amorphous insulating material, it can store embedded charge under high electric fields without charge migration. Pyrex is a well known form of borosilicate glass. A frit containing small particles of such a glass can be made into a paste, screened onto disk 91, and fired. To avoid bowing or warping of disk 91, it is preferable to provide coating 93 on both sides of the disk, as shown in FIG. 4, even if the rotor disk 57 requires only one working surface in a particular application. The fired glass of layer 93 is an amorphous material with good insulating properties and a rigid structure. A center hole 94 is formed in disk 91 for providing space for drive shaft 56.

A plurality of first or positively charged regions 101 and a plurality of second or negatively charged regions 102 are formed in glass layer or coating 93 of the rotor 57. Regions 101 and 102 are preferably interspersed relative to each other and more preferably interspersed circumferentially around the rotor. In this regard, each region 101 and 102 extends radially from the center or center hole 94 of the rotor and is preferably shaped as a sector of a circle and more preferably as a truncated sector of a circle. A positively charged region or positive region 101 is disposed between each adjacent pair of negatively charged regions or negative regions 102. Each positive region 101 is a radial strip of positive charge and negative region 102 is a radial strip of negative charge. Charged regions 101 and 102 together form a charge dipole that is repeated in an ordered radial array as shown extending circumferentially around the rotor 57. Charged regions 101 and 102 on the first working surface 58 of the rotor 57 are preferably aligned with the charged regions 101 and 102 on the opposite second working surface of the rotor, as shown in FIG. 4, but the charged regions 101 and 102 need not be so aligned and be within the scope of the invention. The preferred geometry of the present invention has spaces 103 between the charged areas equal to the length l 104 of the charged areas. Minimum spacing 106 between charged areas is preferably approximately four millimeters to avoid arcing. This assumes a charge density of 10¹⁵ e/cm² and maximum stator amplitude of 800 volts.

The positive charge of region 101 and the negative charge of region 102 are each preferably embedded in glass layer 93 using an ion implantation process. Implantation is achieved using commercial ion implanters using high energy accelerators operating at high energy levels, preferably in the range of 12-200 kEV, to accelerate the charged species into the receiving material. The preferred surface charge density is 10¹⁵ e/cm² for both positive and negative charges, corresponding to implant times of a few minutes. The good insulating properties and rigid structure of glass layer 93 result in the high energy ions implanted in the glass to remain immobile. Immobility of the implanted charged species hinders diffusion and leakage of the charges.

When working surfaces 58 are provided on both sides or a rotor 57, that is surfaces provided with positive and negative regions 101 and 102, a single rotor can be acted on with a torque as large as 700 Newton-meters or 500 foot-pounds in the preferred embodiment.

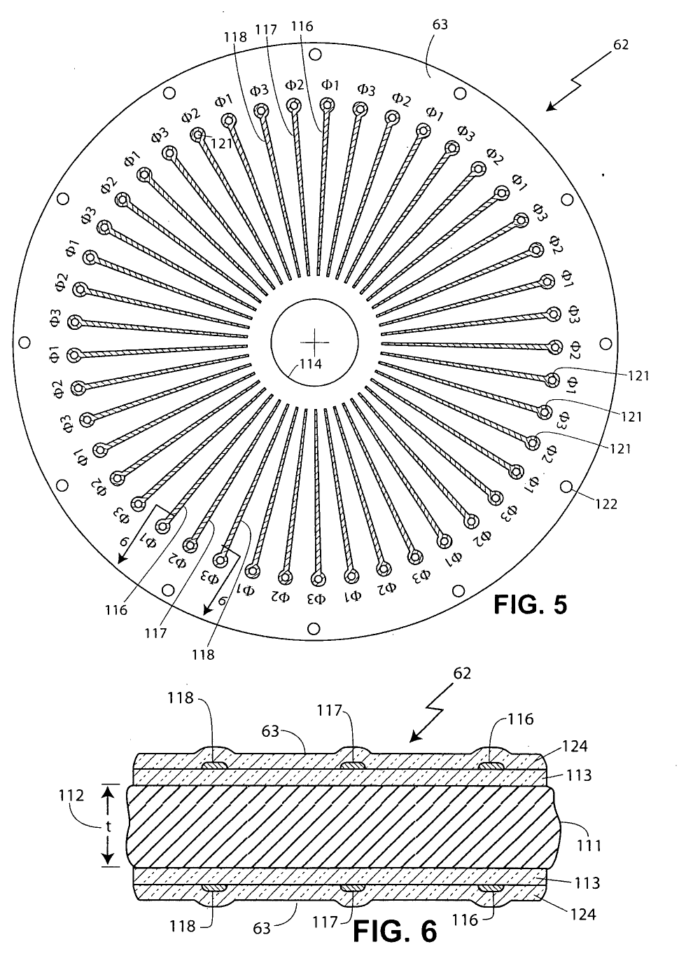

The construction of a stator 62 of the present invention is illustrated in FIGS. 5 and 6. The stator 62 is matched to rotor 57 and has a construction similar to the rotor. In this regard, the stator is formed from a substrate or disk 111 preferably made from the same material as rotor disk 91 and more preferably made of Kovar. The disk 111 has a diameter ranging from 10 to 60 centimeters and preferably approximately 30 centimeters, and has a preferred thickness 112 ranging from one to ten millimeters and preferably approximately five millimeters. Disk 111 is coated with a layer of glass 113 that can be made from the same material as glass layer 93 of rotor 57, and is preferably coated with such glass 113 on both sides of the disk 111. A center hole 114 is provided in the substrate, and the hole 114 is preferably larger than center hole 94 of the rotor 57 to provide clearance for drive shaft 56.

A plurality of first electrodes 116, a plurality of second electrodes 117 and a plurality of third electrodes 118 are formed in glass layer or coating 113 of the stator 62. Metallic electrodes 116, 117 and 118 are preferably interspersed relative to each other and more preferably interspersed circumferentially around the rotor. In this regard, each electrode 116, 117 and 118 extends radially from the center or center hole 114 of the stator. Accordingly, rotor electrodes 116, 117 and 118 are arrayed in repeating order circumferentially around the center of disk 111 on working surface 63. First electrode 116 connects to phase voltage Φ₁, second electrode 117 connects to phase voltage Φ₂, third electrode 118 connects to phase voltage Φ₃, and the sequential pattern of first electrode 116, second electrode 117 and third electrode 118 repeats circumferentially around the stator 62. Electrodes 116-118 on the first working surface 63 of the stator 62 are preferably aligned with the electrodes 116-118 on the opposite second working surface of the stator, as shown in FIG. 6, but the electrodes 116-118 need not be so aligned and be within the scope of the invention. The phase voltages Φ₁, Φ₂ and Φ₃ collectively produce a rotating voltage wave that travels around working surface 63 of stator disk 111. A hole 121 is provided at the outer radial end of each phase electrode, that is near the outer periphery of the stator 62, for receiving a power rod 73 and the material of the respective electrode extends at least partially and preferably entirely around the hole 121. A plurality of additional holes 122 extend through the opposite of surfaces 63 of the stator. Such holes 122 are spaced circumferentially part around the periphery of the stator and are preferably radially outside holes 121 and electrodes 116-118.

Each stator electrode 116-118 is preferably formed from a suitable conductive material such as a thick film paste made from conductive powder that is applied through a screen and is subsequently baked to form hard and smooth conductors on first glass coating 113 (see FIG. 6). A second layer 124 of insulating material that is preferably formed from the same glass coating material as of first layer 113 it is provided over the electrodes and the first glass layer 113 to create a smooth and durable surface that will inhibit arcing between the rotor 57 and the stator 62 as well as between neighboring or adjacent stator electrodes 116-118 during operation. Each of coatings 113 and 124 has a thickness ranging from one to 200 microns and preferably approximately 100 microns, having typical dielectric breakdown strength of 15 kV/mm at a 100 micron thickness. The coatings 113 and 124 provide electrical isolation between the metallic electrodes 116-118, and the second layer 124 additionally inhibits arcing between the rotor 57 and the stator 62.

In other embodiments, the stator 62 may employ glass epoxy such as used in printed circuit boards (PCBs) as the material of the substrate 111, and the electrodes 116-118 can be formed from embedded copper conductors. These PCB disks may include conformal coatings to inhibit arcing.

FIG. 7 is an expanded view of Circle 7-7 of FIG. 2. A nut 131 made from any suitable conductive material such as brass is disposed between each adjacent pair of stators 62 and threaded on the power rod 73 extending through the hole 121 of the stator. A first insulator 132 extends through each hole 121 and around the respective power rod 73 and a second insulator 133 extends around each nut 131 between adjacent stators 62 so as to prevent arcing between high voltage elements. The first and second insulators 132 and 133 are made from any suitable insulating material such as ceramic and are preferably tubular in conformation. At least one suitable conductive element such as compressible coil spring 134 extends between the brass nut 131 and the phase electrode, shown in FIG. 7 as second phase electrode 117, on each working surface 63 of the stator facing the nut to provide gentle electrical contact between the power rod and the phase electrode. Preferably, a plurality of springs 134 extend between the nut 131 and the phase electrode, the springs being circumferentially disposed about the nut and engaging the portion of the electrode extending around the hole 121. Each of the springs 134 seats within a bore 136 provided in the nut. As such, the power rods 73, nuts 131 and springs 134 serve as feed-throughs to distribute drive voltages to the stator electrodes 116-118. For simplicity, second glass layer 124 is not shown in FIG. 7.

A schematic view a rotor 57 overlying a stator 62, revealing an energy converter or motor 31 having 15 poles 141, is illustrated in FIG. 8. For simplicity, the portions of the stator hidden by the rotor are not shown in dashed lines. Each pole 141 includes a charge dipole on the rotor 57 consisting of a positive region 101 and a negative region 102. On the stator 62, each pole 141 includes a set of three phase electrodes 116-118.

In the energy converters of the present invention the number of poles 141 may be of any suitable number and preferably range in number from three to 60. As the number of poles varies the produced torque remains approximately constant for a given charge density and a given amplitude of the phase voltages. This is because for a reduced number of poles the electric field is proportionately decreased by the greater distance between electrodes 116-118, but the embedded charge is proportionately increased by the greater width of the charge regions 101 and 102. Consequently, the number of poles chosen for a given application will depend on such matters as the desired motor RPM, the maximum desired frequency of the synthesized phase voltage waveforms, and the maximum desired current per pole. In a preferred usage, maximum torque is available for smooth acceleration between zero and maximum speed without shifting any gears.

An energy converter controller 52 is provided that provides working voltages for energy converters of the present invention. Commercially available bipolar transistors can achieve voltages up to 1700 volts (V), both positive and negative referred to ground (GND). A typical power transistor can switch a collector current of 5 amps (A) at a frequency of 64 kHz. High band gap semiconductor materials such as silicon carbide may also be used; enabling output voltages in the tens of thousands of volts.

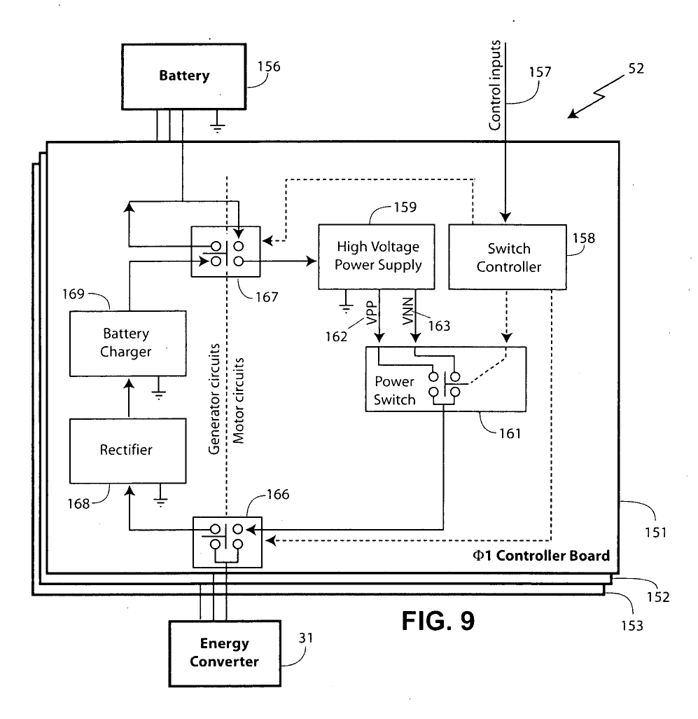

FIG. 9 schematically illustrates one preferred embodiment of controller board or controller 52 of the present invention. The controller 52 preferably includes a first circuit board 151 for controlling first electrode 116, a second circuit board 152 for controlling second electrode 117 and a third circuit board 153 for controlling third electrode 118, each of which is preferable substantially identical in construction but configured for the respective electrode 116-118. Circuit board or controller 116 associated with the first electrode or Φ₁ is illustrated in FIG. 9. Input power is provided by a battery 156 or other suitable energy storage device such as a fuel cell. Power is delivered to energy converter 31 using polyphase drive voltages applied to one or more stators 62. Control inputs 157 preferably include accelerator position (torque demand), brake position, and load angle. These inputs are received by a switch controller 158 which includes a computer or other processor for calculating pulse durations and timing. Power pulses are applied to the phase drive electrodes using a high voltage power supply 159 together with a power switch 161 coupled to the controller 158 and the power supply 159. High voltage power supply 159 provides a positive supply voltage VPP 162 and preferably an equal and opposite negative supply voltage VNN 163 to the power switch 161. In one preferred embodiment, the Motor Mode power switch 161 includes PNP transistors (not shown) for driving towards the VPP rail 162 and NPN transistors (not shown) for driving towards the VNN rail 163. Motor Mode power switch 161 has three positions: feeding power from VPP supply 162 to the energy converter; no connection; and feeding power from VNN supply 163 to the energy converter. First and second power switches 166 and 167 control the direction of power transfer between the energy converter 31 and battery 156; the connection can be “forward power” for motor action in Motor Mode of the converter 31, “reverse power” for generator action in Generator Mode of the converter 31, and no-connection in Pause Mode for providing a pause between motor and generator action, as well as providing a way for the vehicle to coast without accelerating or braking. The position of switches 166 and 167 is controlled by switch controller 158, as shown by the dashed lines from the controller 158 to switches 166 and 167 in FIG. 9. For the case of generator mode, AC power is generated between stator electrodes 116-118 by moving charges, that is the embedded charge regions 101 and 102, on the rotor 57. This AC power is fed via switch 166 to rectifier 168 which produces DC power and feeds it to battery charger 169. Battery charger 169 feeds power through switch 167 to battery 156. If the power source is another form of energy storage device, a different signal conditioning device may be used in place of battery charger 169.

The physical implementation of charge dipoles on a working surface 58 of a rotor 57 opposed by spaced apart poly-phase electrodes 116-118 on a stator working surface 63 is equally well suited to operation of energy converter 31 as a motor or as a generator. When operated as a motor, electrical power is applied to the stator electrodes 116-118 and mechanical power is extracted from the rotor 57. When operated as a generator, mechanical power is applied to the rotor 57 and electrical power is extracted from the stator electrodes 116-118. Except for changes in the control algorithm and power connections, no reconfiguration of the energy converter or machine 31 is required to switch between operation as a motor and operation as a generator.

In operation and use of energy converter 31 in a vehicle 32, controller 52 interprets control inputs asserted by the vehicle driver and one of three modes is entered: Motor Mode, Generator Mode, or Pause Mode. Pause Mode is used during transitions between the other two modes. In Motor Mode the vehicle 32 is powered and the controller 52 periodically computes a pulse width for each phase drive to meet the instantaneous torque demand. If the vehicle driver applies the brakes, the energy converter 31 will enter Generator Mode wherein the controller 52 extracts power from the poly-phase voltages generated at the stator electrodes 116-118 and uses this power to recharge a battery or other energy storage device.

In Motor Mode, a traveling voltage wave is created by applying a poly-phase (multi-phase) waveform to the electrodes 116-118 wherein the phases are applied in repeating order. The traveling wave has an unambiguous direction when at least three phases are used. One preferred embodiment of the invention employs the simplest choice of three phases; however, any number of phases greater than or equal to three can be used. In the present invention the electrodes 116-118 are radially arrayed around the center of stator disk 111, thus creating a rotating voltage wave for driving rotor 57.

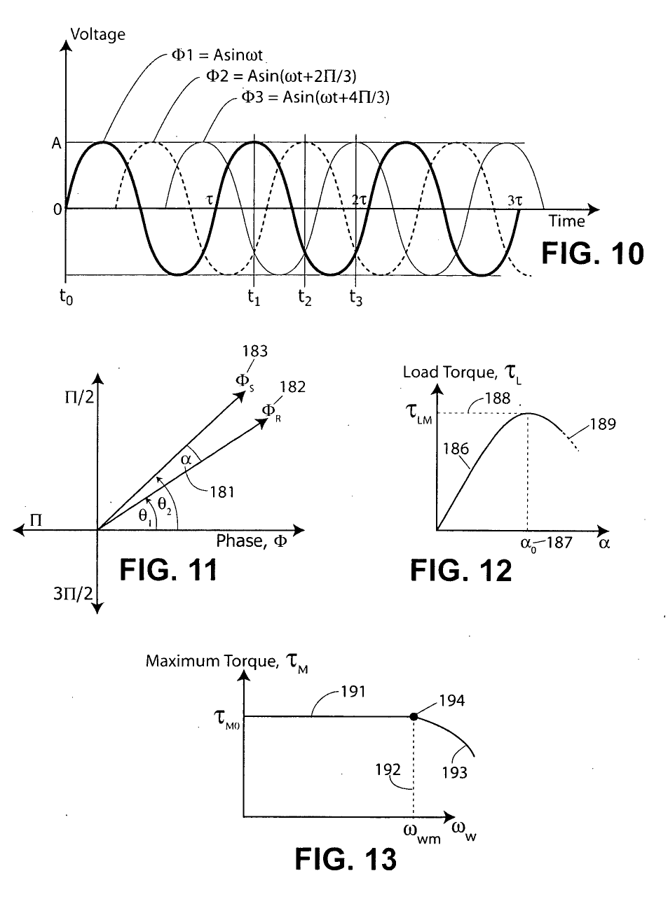

A graph of voltage versus time for a three phase voltage traveling wave produced by stator 62 is illustrated in FIG. 10. The formulas for each of the three phase voltages are shown, where A equals amplitude in volts, w equals angular velocity in radians per second, and t equals time in seconds. At time t₁, electrode 116 or Φ₁ is peaking; at time t₂ electrode 117 or Φ₂ is peaking, and at time t₃ electrode 118 or Φ₃ is peaking. Thus the peak of the wave is traveling from electrode to electrode on the surface of the stator 62. For steady state conditions (constant vehicle speed), the phase voltages have a constant amplitude and a constant period, t. The angle of electrode Φ₁ at t₀ is arbitrarily defined as zero phase, providing a phase reference.

A graphical definition of motor load angle α 181 is illustrated in FIG. 11, where θ₁ is the instantaneous angle of the rotor phase vector Φ_{R} 182, relating to the rotary encoder disk 76 attached to the drive shaft 56. Encoder disk 76 and sensor 77 operate in combination to measure the rotor phase angle. Angle θ₂ is the instantaneous angle of the stator phase vector ΦS 183; this is the known phase of the applied voltage waveform. Angles θ₁ and θ₂ are referred to the same phase reference. Angle θ₂ is the same as the rotor phase angle under zero load, that is Φ_{R} and Φ_{S} are coincident under the no load condition. However, as a load is applied, Φ_{R} lags Φ_{S} by an angle α as shown. It is convenient in the motor controller 52 to use a as a control parameter; preferably a control algorithm is applied to control a within a narrow range for high motor efficiency.

Although a three-phase waveform has been described for powering energy converter 31, it is appreciated that more phases can be used for smoother torque performance or for fault tolerant energy converters wherein a phase can be defective and the converter will still operate.

Load angle is a useful parameter for controlling electrostatic motors; it is the angular difference between the actual position of the rotor 57 under the current instantaneous load, and the theoretical position of the rotor if there were no load.

FIG. 12 is a graph of load torque τ_{L} 186 versus load angle α. A preferred operating condition is at a load angle α₀ 187 when motor efficiency is high and load torque is maximized at τ_{LM} 188. If operation is attempted using a large load angle such as at operating point 189, the rotors may lose synchronism with the applied phase voltages.

The design intent of a gearless motor is shown in FIG. 13. Maximum motor torque τ_{M} is plotted against the angular velocity of the vehicle wheel, cow, for constant phase voltage amplitude. Maximum torque τ_{M0} 191 is available up to a maximum angular velocity ω_{wm} 192 as shown. At faster speeds, the torque falls off near point 193 due to inadequate switching speed of the drive electronics, and/or motor losses. It is preferable to size the energy converter or motor 31 for operating point 194, thereby ensuring maximum torque availability up to the maximum vehicle speed, with no gear-shifting required.

The force equation for an electrostatic motor is:
Fₑₛ=qE
where charge q is acted on by electric field E, and Fₑₛ is the generated electrostatic force. Fₑₛ and E are co-linear vectors. On rotor disk 91, the E vectors that generate torque are all in the same plane. This leads to the preferred implementation using parallel working surfaces. Since E is proportional to voltage, electrostatic motors respond to operating voltage rather than to operating current.

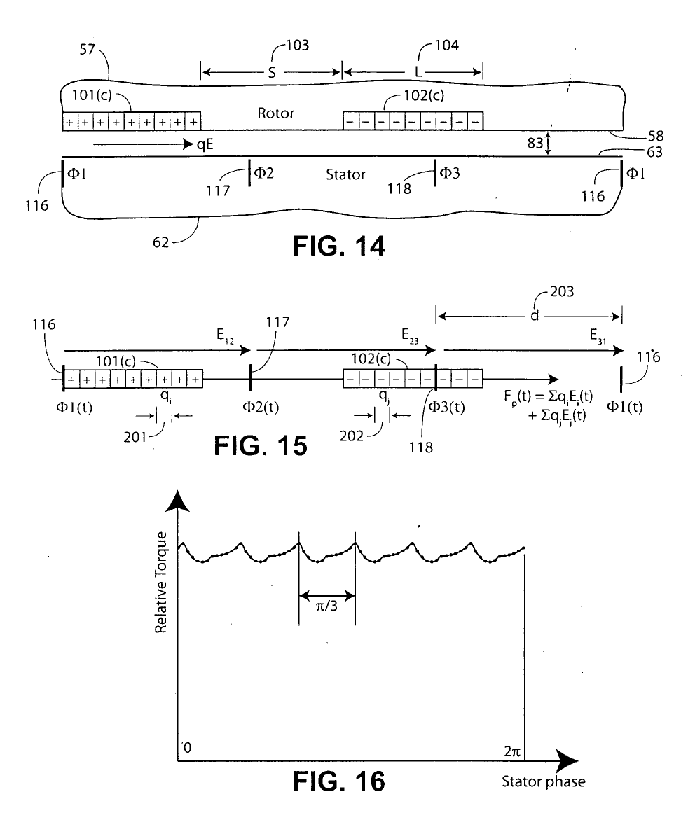

A schematic illustration of a pair of face-to-face working surfaces 58 and 63 on rotor 57 and stator 62, with an air gap 83 between them is shown in FIG. 14. The mechanical rigidity of rotor disk 91 and stator disk 111 facilitate the maintenance of a constant gap 83 over a large radius for the rotor and stator. In the direction perpendicular to the page, charge region 101 of FIG. 3 has been collapsed into a line of positive charge 101(c) at the centroid of charge region 101. Similarly, charge region 102 of FIG. 3 has been collapsed into a line of negative charge 102(c) at the centroid of charge region 102. Lines of charge 101(c) and 102(c) have constant linear charge density corresponding to constant area charge density in regions 101 and 102. The geometry shown has length 104 of the charge area equal to the separation 103 between them. Equidistant stator electrodes 116-118 labeled Φ₁-Φ₃ are shown in repeating order. In the gap 83 between rotor 57 and stator 62, a force of magnitude q_{E} is developed, where q_{E} is summed over all of the positive and negative charge elements in the given pole 141 of the energy converter 31, and E varies from element to element according to the instantaneous values of the applied phase voltages.

A linear model of energy converter 31 is shown in FIG. 15. For convenience, it is formed as an overlay of the rotor and stator elements, that is charged regions 101(c) and 102(c) of the rotor 57 and electrodes 116-118 of the stator 62. If the gap 83 between the opposed working surfaces of an adjacent rotor and stator is small compared with the length 104 of a charge region 101(c) or 102(c), the error in this simplification is small. Incremental elements of positive charge qᵢ 201 and incremental elements of negative charge qⱼ 202 are shown. The total force is the sum of the forces acting on all of the incremental charge elements. The phase voltages vary with time, and the electric field between each pair of electrodes 116-118 is shown. For example, E₃₁ is Φ₃(t)−Φ₁(t) divided by the distance d 203 between them. The force produced by one pole 141 of the energy converter 31 is:
Fₚ(t)=Sᵢⱼ(qᵢEₙₘ(t)+qⱼE_{pq}(t))

where nm may be 12 and pq may be 23 for example. Applying the following assumptions and intermediate results enables calculation of the maximum power developed by a single pair of working surfaces for a motor of the present invention:

| | |
|---|---|
| Stator diameter | 30 centimeters |
| Implanted charge density | 10¹⁵ e/cm² (positive and negative) |
| Stator voltage waveform | Sinusoid with Aₘₐₓ = 800 V and fₘₐₓ = 250 Hz |
| Number of motor poles | 15 |
| Mean torque output | 352 N-m or 260 ft-lb |
| Max angular velocity of | 105 radians/sec or 1,000 RPM |
| motor | |
| Maximum power | 36.2 kW or 48.6 HP @ 98% efficiency |

With respect to vehicle 32 illustrated in FIG. 1, if the desired maximum vehicle speed is 80 miles per hour, and if the wheel diameter 41 is three feet, the maximum rotation speed of wheel 34 is calculated to be 12.5 revolutions per second or 750 RPM. In reference to FIG. 15 the maximum motor RPM is 1000 RPM. Thus the gear ratio required for this scenario is approximately 1.3, close to 1.0. This means that both gears 37 and 38 can be small. It also means that good performance can be achieved with an energy converter or motor 31 that runs slowly compared with equivalent internal combustion engines in use today. The motor 31 of the present invention will run almost silently, with no gear switching required. It will also have low weight, small size, and high efficiency. Frictional losses are limited to motor shaft bearing friction, plus drag on the rotors 57 that depends on the gap 83 medium.

The relatively small air gap 83 provides enough space for a durable and reliable mechanical assembly yet does not materially affect the force vector produced by energy converter 31. Using this gap and the given geometries of the preferred embodiment, the useful component of the force vector is greater than 99% of the total force generated. Also, the force normal to rotor 57 during operation averages to zero over the space of each motor pole 141. This is a consequence of the symmetry of the drive scheme; it requires that the charge densities in regions 101 and 102 of FIG. 3 are equal and opposite and also that the phase voltages of FIG. 10 are centered at zero volts. If these conditions are met there will be little tendency for rotor 57 to depart from a centered track as it rotates in an energy converter 31 of the present invention.

When the energy converter 31 is in Motor Mode, the control scheme of controller 52 takes advantage of the control power of a computer or digital processor contained in switch controller 158, performing periodic calculations of pulse widths to be applied to the phase drives. A maximum frequency for a stator voltage waveform (phase drive voltage) is 250 Hz. A modern digital processor can apply a control algorithm to compute pulse widths in less than a microsecond, providing over 4,000 calculations per sinusoidal cycle at 250 Hz. Given the frequency and amplitude of the current motor cycle plus the torque demand and load angle, the algorithm within the computer of switch controller 158 can compute the desired amplitude and frequency of the next motor cycle. Once this is established, a smooth transition to the new amplitude and frequency can be implemented using the fine grain adjustments provided by the variable pulse widths. In this manner smooth phase drive waveforms can be synthesized, including adaptation to instantaneous demand. Losses in the PNP and NPN power transistors of power switch 161 represent a substantial fraction of total power losses. Operating in the switch mode described allows these power transistors to operate at high efficiency, reducing power losses in controller 52 and increasing the overall efficiency of the energy converter 31.

FIG. 16 is a graph depicting phase quantization error for the preferred embodiment modeled in FIG. 15. A phase error occurs because the field is quantized by providing drive voltages at electrodes 116-118 that are spaced apart. If the electrodes have zero space between them, the rotating voltage wave is smooth and continuous in space as well as in time, and this results in smooth and continuous torque. For the rotor 57 and stator 62 geometries of FIG. 3 and FIG. 5, modeled as shown in FIG. 15, the torque variation repeats every Π/3 radians or 60 degrees, as shown in FIG. 16. This represents a standard deviation of 2.8% based on the mean. Many strategies exist for reducing this variation in torque: they include shaping the stator electrodes 116-118, staggering the phase (mounting angle on the drive shaft 56) between different pairs of working surfaces 58 and 63, and tailoring the phase drive waveforms.

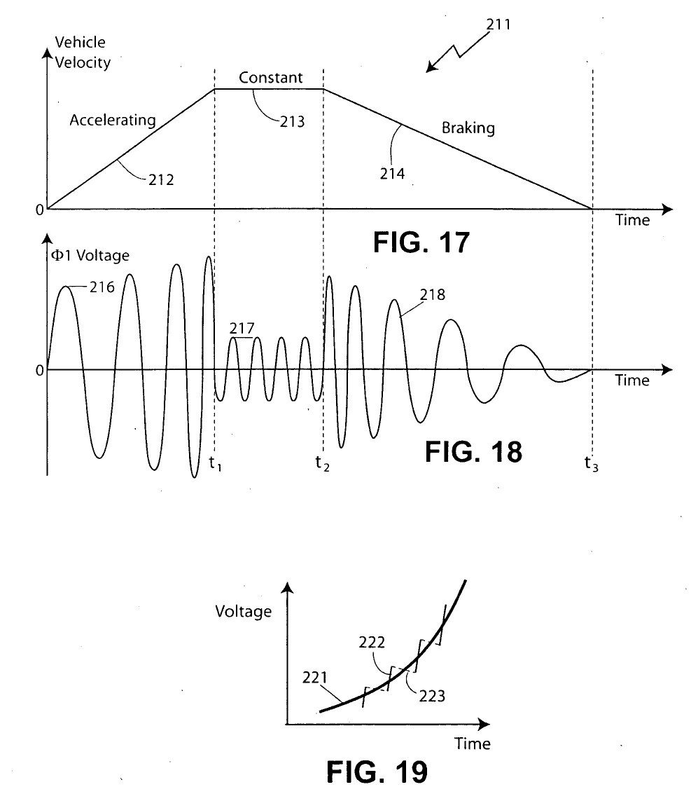

A graph of velocity versus time for a simple scenario 211 for a trip of vehicle 32 is shown in FIG. 17. Scenario 211 includes an acceleration segment 212, a constant velocity segment 213, and a braking segment 214. These segments will correspond with matching modes of the energy converter set.

A schematic depiction of Φ1 variations in accordance with the scenario of FIG. 17 is illustrated in FIG. 18. Φ2 and Φ3 will be similar, for both motor and generator modes of the energy converter 31. Controller 52 can produce such waveforms. Motor torque varies directly with the amplitude of the drive voltage. In acceleration segment 212, the controller 52 enters Motor Mode and generates Φ1 with a starting amplitude 216 as shown, representing substantial torque to produce the acceleration. The losses due to vehicle drag increase as the vehicle 32 gathers speed. Since acceleration rate 212 is constant, Φ1 has to increase in amplitude until t₁, to provide torque for acceleration and for overcoming drag. Φ1 also increases in frequency during this period, because the frequency of the phase voltages relates directly to vehicle speed. Between t₁ and t₂ is constant velocity segment 213 of FIG. 17. The frequency in this segment is the same as at the end of acceleration segment 212 because the vehicle speed is unchanged; however constant velocity amplitude 217 is reduced to provide just enough power to overcome vehicle drag and maintain constant speed. At t₂, the vehicle driver begins to brake, and the controller 52 enters Generator Mode. Voltage 218 is induced on the Φ1 stator electrodes by the generator action of the embedded charges on the rotor 57 moving adjacent the stator electrodes 116-118. This re-generated energy is preferably used to charge the vehicle battery or other power storage device. The vehicle 32 comes to a stop at time t₃ and induced voltage 218 falls to zero.

FIG. 19 is a graph depicting pulse action as described with respect to FIG. 9. The goal is to produce a voltage waveform 221 that is generally sinusoidal but whose amplitude or frequency may vary, as described in reference to FIG. 18. Steep rising segments 222 correspond to the effect of connecting VPP to a set of stator electrodes or phase drive electrodes 116-118 for the duration of a pulse. Dotted line segments 223 correspond to the period between pulses, when leakage in various components cause the output voltage to decay slowly.

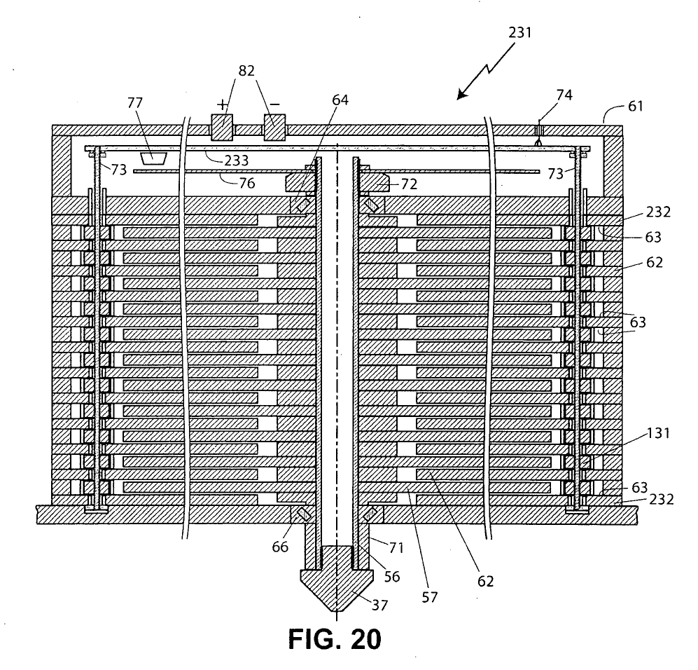

Other embodiments of the energy converter of the present invention can be provided that are scalable. The modularity of energy converter 31 of FIG. 2 supports stacked energy converters having any reasonable number of rotors 57 and stators 62; for example high-stacked energy converter 231 of FIG. 20 has twelve stators 62 and eleven rotors 57. The energy converter 231 is substantially similar to energy converter 31 and like reference numerals have been used to describe like components of converters 31 and 231. Such a high-torque energy converter 231 may be suitable for a tractor, bus, truck, or train engine for example. On starting it acts like a traction engine, with full torque available at zero speed. The stators 232 at the top and bottom of the stack are each substantially identical to stator 62 except that they are each one-sided, having a working surface 63 including stator electrodes 116-118 on only one of their faces 63. The other rotors 57 and stators 62 are all two-sided. It can be seen that rotor and stator components are similar or identical for energy converter 31 and for high-stacked energy converter 231; this commonality and modularity enables marketing of a line of energy converters having varying power. High-stacked energy converter 231 is shown with a controller board 233 that produces a relatively higher operating current than that of controller board 52 of FIG. 2.

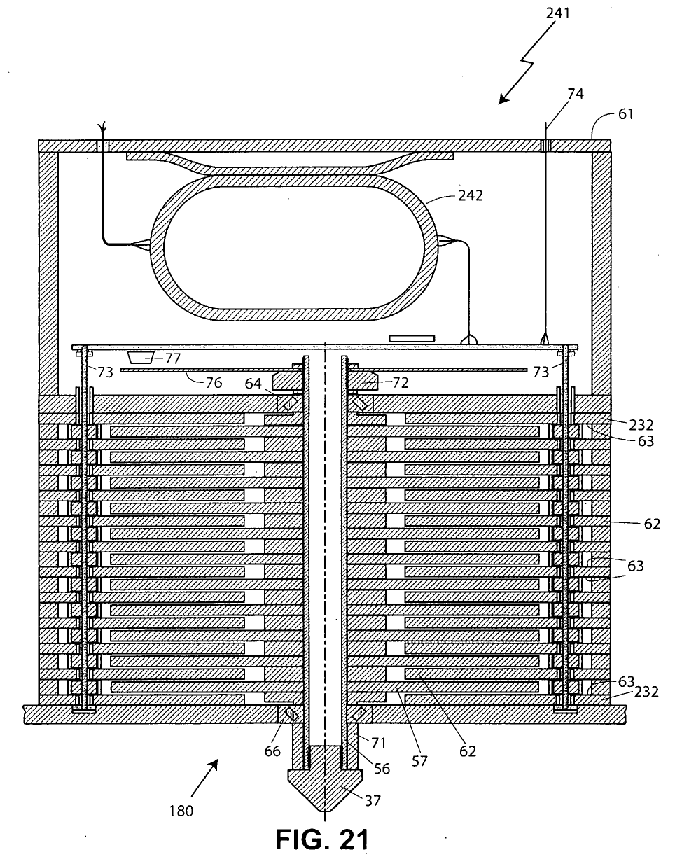

In a further embodiment of the energy converter of the present invention, a stacked industrial energy converter 241 having a high power 3-phase transformer 242 is shown in FIG. 21. The converter 241 is a synchronous converter, wherein the speed of the converter is locked to the frequency of the supply voltage. For a 60 Hz supply frequency and a 15 pole energy converter, the motor speed is 240 RPM. Since motor speed varies inversely with the number of poles 141, different speeds can be provided. In addition, the output can be geared to obtain a wide range of output speeds.

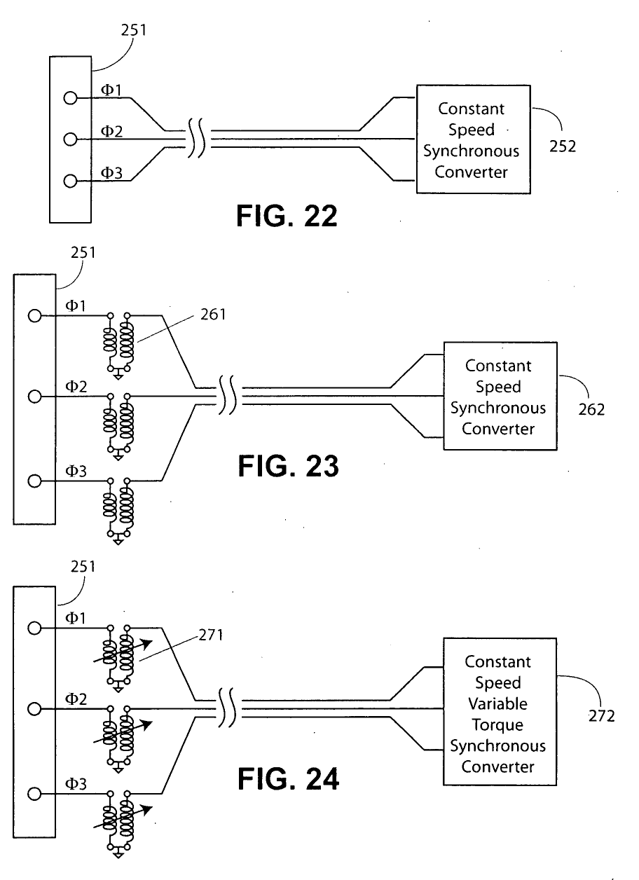

FIGS. 22-24 depict variations on the three-phase power supply to motor 180 of FIG. 21. In FIG. 22, three phase power is connected directly from the mains 251 to the energy converting portion of converter 252. The converter 252 is preferably a constant speed synchronous converter. In FIG. 23 a three-phase power transformer 261 increases the working voltage to increase the available torque in the energy converting portion of converter 262, which is also a constant speed synchronous converter. In FIG. 24 variable power transformer 271 provides variable torque characteristics in the energy converting portion of converter 272, which is preferably a constant speed variable torque synchronous converter. It may be useful to increase the startup torque temporarily, particularly for heavy industrial loads.

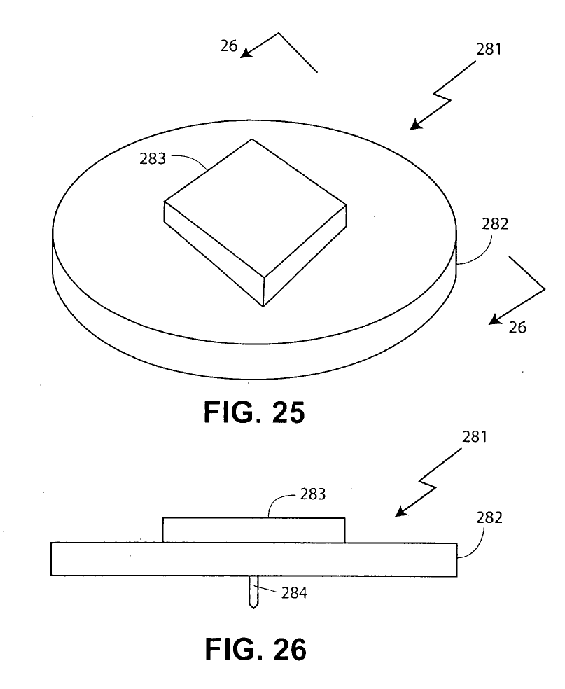

The energy converter of the present invention can be used in other than vehicles. In another embodiment, an energy converter of the invention is utilized in a compact motorized tool 281 as illustrated in FIGS. 25 and 26. Tool 281 has a pancake shape and a size that can be grasped and held in a human hand. The tool employs a stack of one or more rotors 57 and stators 62, configured in any suitable manner such as in energy converter 31, encased in a durable cylinder 282. Attached to the cylinder 282 in a form suitable for grasping by an operator is a raised feature or housing containing a power pack 283, which may be a battery plus controller as previously described or a fuel cell. Alternatively, power pack 283 may condition three phase power delivered by a cable (not shown). Any suitable tool such as a drill bit 284 may be powered by tool 281. Using just one rotor 57 and stator 62, cylinder 282 may only be approximately three millimeters in height or thickness. Stacked versions of the energy converter or motor of the present invention have higher torque and yet have a low profile compared with common electromagnetic energy converters or motors. The motorized tool 281 can be hand-held for example, enabling convenient access to hard-to-reach areas for drilling, sanding, polishing, or similar applications.

It can be seen from the foregoing that an improved replacement for heretofore provided electromagnetic energy converters and electrostatic motors has been provided. Improvements relative to electromagnetic motors include higher energy efficiency, higher reliability, a more compact size, higher power-to-weight ratio, and reduced manufacturing costs. With respect to prior art electrostatic motors, improvements include higher surface charge density which permits higher torque for a given sized motor (higher energy density), lower manufacturing costs, no electrical connections for the moving rotor element, planar working surfaces on the rotor and stator, improved reliability and higher energy efficiency. The energy converter of the present invention is modular and scalable. For each converter diameter, torque and power can be adjusted via the number of rotor and stator disks employed in the converter stack. Thus a set of standardized disks can support a wide range of applications having varying torque and power requirements. This can lead to increased manufacturing volume of the disks, and lower production costs. In addition to the foregoing, an energy efficient energy converter controller has been provided. A preferred embodiment of the controller employs a variable frequency control algorithm.

The electrostatic energy converter of the present invention uses electrostatic forces operating on face-to-face working surfaces to create torque. Preferably the working surfaces are provided on thin disks and are flat. The generated torque varies with voltage rather than with current as in an electromagnetic energy converter. These features enable a compact energy converter that produces high torque at high energy efficiency.

High reliability is achieved through the mechanical and electrical simplicity of the energy converter of the present invention. No electrical connections are required for the rotor; in contrast with motors that require armatures or brushes. For a given power output, the energy converter hereof runs at a temperature lower than a corresponding electromagnetic energy converter because of lower operating current. Generally, lower operating temperatures result in higher reliability.

What is claimed is:

1. An electrostatic energy converter comprising a rotor having a working surface provided with a plurality of distinct charged regions, a stator extending parallel to the rotor and having a working surface facing the working surface of the rotor and being provided with a plurality of spaced-apart electrodes and a power supply coupled to the electrodes.

2. The energy converter of claim 1 wherein the stator has a center and the plurality of spaced-apart electrodes extend radially from the center of the stator.

3. The energy converter of claim 2 wherein the plurality of spaced-apart electrodes are circumferentially spaced apart around the stator.

4. The energy converter of claim 1 wherein the rotor has a center and the plurality of distinct charged regions extend radially from the center of the rotor.

5. The energy converter of claim 4 wherein the plurality of distinct charged regions are circumferentially spaced apart around the rotor.

6. The energy converter of claim 5 wherein the plurality of distinct charged regions include repeating pairs of positively and negatively charged regions extending around the rotor.

7. The energy converter of claim 1 wherein each of the plurality of distinct charged regions is a region of embedded electric charges.

8. The energy converter of claim 7 wherein the working surface of the rotor includes a layer of an insulting material and the embedded electric charges are implanted in the layer of insulating material

9. The energy converter of claim 8 wherein the insulating material is selected from the group of materials consisting of ceramic, glass and plastic.

10. The energy converter of claim 1 wherein the power supply is configured to provide poly-phase voltages to the plurality of spaced-apart electrodes.

11. The energy converter of claim 10 wherein the power supply is configured to create an electric wave rotating on said plurality of spaced-apart electrodes about a center of the stator for interacting with the plurality of distinct charged regions of the rotor to impart torque on the rotor so as to provide an electrostatic motor.

12. The energy converter of claim 1 wherein the power supply is configured to extract poly-phase power generated at the plurality of spaced-apart electrodes.

13. The energy converter of claim 1 wherein each of the rotor and the stator are formed from a metal disk and the respective working surface is formed from a layer of insulating material overlying the metal disk.

14. The energy converter of claim 1 further comprising an additional rotor extending parallel to the first-named stator and having a working surface provided with a plurality of distinct charged regions, the stator being disposed between the first-named rotor and the additional rotor, and an additional stator extending parallel to the additional rotor and having a working surface facing the working surface of the additional rotor and being provided with a plurality of spaced-apart electrodes.

15. The energy converter of claim 1 wherein the rotor and stator are separated by a gap.

16. The energy converter of claim 15 wherein the gap is a vacuum gap.

17. The energy converter of claim 15 wherein the gap is filled by a fluid selected from the group consisting of gas, air and liquid.

18. A power and control unit for use with an electrostatic motor having a torque demand and electrodes driven by a poly-phase drive scheme having at least three phase voltages comprising a power supply having a positive rail and a negative rail, a switch control unit configured to receive control inputs and adapted to receive the torque demand for calculating pulse widths for at least one of the phase voltages as a function of the torque demand and a power switch coupled to the switch control unit for making no connection or connecting one of the positive rail and the negative rail to selected electrodes for delivering the desired phase voltages to the selected electrodes using current pulses of the calculated width.

19. The power and control unit of claim 18 wherein the switch control unit is configured to calculate the pulse widths using a control algorithm that produces smooth variations in the phase voltages while adapting frequency and amplitude of the phase voltages on a cycle-by-cycle basis to accommodate changes in speed and torque demand of the electrostatic motor.

20. A transportation vehicle comprising a support frame and a plurality of wheels rotatably mounted to the support frame, at least one electrostatic motor carried by the support frame and coupled to at least one of the wheels, the electrostatic motor including a rotor having a working surface provided with a plurality of distinct charged regions and a stator extending parallel to the rotor and having a working surface facing the working surface of the rotor and being provided with a plurality of spaced-apart electrodes and a power supply coupled to the electrodes.

21. A compact motorized tool for being held and operated by a human hand comprising a housing adapted for grasping by the human hand, an electrostatic motor carried by the housing and including a rotor having a working surface provided with a plurality of distinct charged regions and a stator extending parallel to the rotor and having a working surface facing the working surface of the rotor and being provided with a plurality of spaced-apart electrodes, and a tool coupled to the rotor.
